(19) United States
(12) Patent Application Publication
(10) Pub. No.: US 2005/0112830 A1
(43) Pub. Date: May 26, 2005

(54) Ultra shallow junction formation

(76) Inventors: Amitabh Jain, Allen, TX (US); Lance S. Robertson, Rockwall, TX (US)

Correspondence Address: TEXAS INSTRUMENTS INCORPORATED, P O BOX 655474, M/S 3999, DALLAS, TX, 75265, US

(21) Appl. No.: 10/816,776

(22) Filed: Apr. 2, 2004

Related U.S. Application Data
(63) Continuation-in-part of application No. 10/721,985, filed on Nov. 25, 2003.

(51) Int. Cl. H01L 21/336

(52) U.S. Cl. 438/301

(57) ABSTRACT

The invention describes a method for forming ultra shallow junction formation. Dopant species are implanted into a semiconductor. Solid phase epitaxy anneals and subsequent ultra high temperature anneals are performed following the implantation processes.

This application claims priority and is a continuation-in-part of prior patent application Ser. No. 10/721,985 filed Nov. 25, 2003.

### FIELD OF THE INVENTION

The present invention relates to a method for forming ultra shallow junctions in integrated circuits.

### BACKGROUND OF THE INVENTION

As metal oxide semiconductor (MOS) transistor dimensions are reduced it is becoming increasingly important to be able to form ultra shallow source and drain extension junction regions in order to minimize the short channel effects. In addition, reduction of the junction depth may allow engineering of the pocket implant for improved channel mobility. Ideally, the implanted dopant should be placed close to the surface and with high active doping concentrations at the surface after various thermal annealing processes. However, a reduction of junction depth, very frequently, is accompanied by reduction of active dopant concentration leading to an increase in the parasitic resistance in the MOS transistor. This is illustrated in FIG. 1.

In a pn junction the junction is often defined as the point where the n-type concentration equals the p-type concentration. Typically junctions are formed by implanting n-type dopants into a p-type semiconductor or vice versa. Shown in FIG. 1 are concentration versus distance graphs 20, 30 showing the formation of a typical pn junction. Starting with a semiconductor substrate 10 with dopant concentration C_{S} 60, dopant species of an opposite type are implanted into the substrate. For example, if the substrate is p-type, n-type dopant species are implanted into the substrate to form an n-type region at a particular junction depth. Referring now to FIG. 1, dopant species are implanted into the semiconductor substrate to form region 15. The corresponding concentration versus distance graph 20 is shown adjacent to the implanted region 15. The concentration curve 40 shows that the implanted species equals the semiconductor substrate doping concentration Cₛ 60 at a distance X₁ below the surface of the substrate. Following the dopant implantation process a thermal anneal is performed to activate the implanted species and anneal out any damage that may have occurred to the crystalline lattice during the implantation process. As shown in FIG. 1, during the thermal annealing process the implanted species diffuse into the substrate 10 as shown by the second concentration versus distance graph 30 to form region 70. Here the concentration curve 50 is broader and wider than the as implanted concentration profile 40 resulting in the junction depth X₂ shown in the Figure. This diffusion limits the minimum junction depth (i.e. X₂) that can be obtained using currently available methods. Typical thermal annealing conditions are 550° C. to 1100° C. for times ranging from seconds to many minutes. One approach to forming ultra shallow junctions is to perform solid phase epitaxial recrystallization of ion implanted layers to achieve high activation with minimal diffusion. However, this technique leaves a high degree of crystal disorder and unactivated dopant beyond the recrystallization interface. Given the constraints of short channel length MOS transistors there is a need for a method to form ultra shallow junctions with high dopant concentration and reduced junction depths.

### SUMMARY OF INVENTION

The instant invention describes a method for forming ultra shallow junctions in semiconductor devices. In particular the method comprises implanting a dopant species into said semiconductor and annealing the implanted semiconductor with a solid phase epitaxy anneal and a subsequent ultra high temperature anneal comprising annealing temperatures from 1050° C. to 1350° C. for times from 0.5 milliseconds to 3 milliseconds. An optional amorphizing implant may be performed prior to or following the implanting the dopant species.

### BRIEF DESCRIPTION OF THE DRAWINGS

For a more complete understanding of the present invention and the advantages thereof, reference is now made to the following description taken in conjunction with the accompanying drawings, wherein like reference numerals represent like features, in which:

FIG. 1 shows the formation of a junction according to the prior art.

FIGS. 2(a)-2(b) are cross sectional diagrams showing an embodiment of the instant invention.

FIG. 3 is a cross section diagram showing a MOS transistor fabricated according to an embodiment of the instant invention.

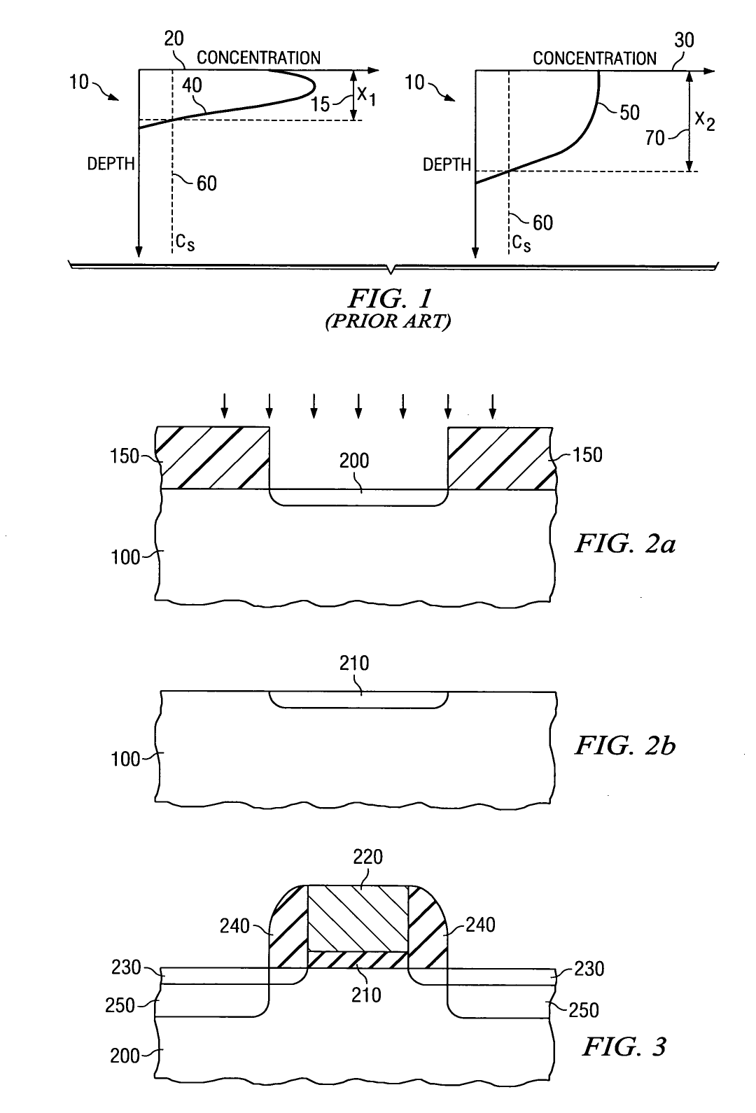

### DETAILED DESCRIPTION OF THE INVENTION

The instant invention is described with reference to FIGS. 2(a) and 2(b). The Figures show the formation of an ultra shallow junction in an integrated circuit.

As shown in FIG. 2(a) a patterned photoresist layer 150 is formed on a semiconductor 100. The semiconductor can comprise a substrate, an epitaxial layer, or any semiconductor suitable for forming a junction. The junction so formed in the semiconductor 100 can be formed as part of a MOS transistor, a bipolar junction transistor (BJT) or any semiconductor device that requires an ultra shallow junction for proper operation. The embodiment illustrated in FIGS. 2(a) and 2(b) shows only the formation of an ultra shallow junction and any associated semiconductor device is not shown for clarity. In a first embodiment of the instant invention the semiconductor is doped n-type and p-type dopant species such as boron, gallium, and indium are implanted through the opening in the photoresist layer 150 and into the semiconductor to form the implanted region 200. In a second embodiment of the instant invention the semiconductor 100 is initially p-type and n-type dopants such as arsenic, phosphorous, and antimony are implanted through the opening in the photoresist layer 150 to form the implanted region 200. In either embodiment it is important that the implanted region 200 be amorphous after the dopant implantation process. Therefore an optional amorphous implant process can be performed before or after the implantation of the dopant species to form an amorphous region. In the embodiment where the optional amorphous implant is performed prior to the implantation of the dopant species, the dopant species are implanted into the amorphous region. In an embodiment of the instant invention this can be accomplished by implanting silicon, germanium, antimony, indium, arsenic, neon, argon, krypton, xenon, or other suitable species into the semiconductor to form an amorphous region followed by the implantation of the required dopant species.

Following the implantation of the dopant species and the optional amorphizing implant species (if necessary) to form region 200, the photoresist layer 150 is removed and thermal annealing is performed. Initially a solid phase epitaxy (SPE) anneal is performed to recrystallize the implanted amorphous region 200. In an embodiment the SPE anneal can be from 500° C. to 950° C. for a few seconds to hundreds of seconds. In a further embodiment the SPE anneal is performed at temperatures around 900° C. As stated previously the SPE anneal will result in recrystallization of the implanted amorphous region 200 and activation of the implanted dopant species. The SPE anneal will also leave dislocation loops and other crystalline defects in the semiconductor. Such crystalline defects can have a deleterious effect on device performance. In order to reduce and/or eliminate the presence of crystalline defects while maintaining high dopant activation with minimal dopant diffusion ultra high temperature (UHT) annealing is performed following the SPE anneal. In an embodiment of the instant invention the UHT anneal comprises annealing the implanted region 200 at temperatures from 1050° C. to 1350° C. for 3 milliseconds to 0.5 milliseconds. The UHT anneals can comprise one such anneal or any number of annealing cycles. UHT annealing will result in the ultra shallow junction shown in FIG. 2(b). Diffusion of the implanted dopant species is limited by the short times of the UHT anneal and the resulting active dopant concentration is high due to the high temperatures of the UHT anneal. Although the above embodiment illustrated a single implanted region it should be noted that any number of implanted regions (and therefore ultra shallow junction regions) could be simultaneously formed using the method of the instant invention. The junctions can comprise portions of numerous semiconductor devices such a MOS transistors and bipolar junction transistors.

A MOS transistor formed according to an embodiment of the instant invention is shown in FIG. 3. The transistor gate dielectric layer 210 is formed on a semiconductor 200. The gate dielectric layer 210 can comprise silicon oxide, silicon oxynitride, or any suitable dielectric layer material. A MOS transistor gate electrode 22 is formed on the gate dielectric layer 210. The gate electrode 220 can comprise doped polycrystalline silicon, a metal, or any suitable conductor material. Following the formation of the gate electrode the drain and source extension regions 230 are formed. In an embodiment of the instant invention forming the drain and source extension regions 230 comprises implanting n-type or p-type dopants into the semiconductor 200. An optional amorphizing implant can be performed prior to or following the dopant implantation process to form amorphous regions adjacent to the gate electrode 220 in the semiconductor 200. The n-type dopants and comprise arsenic, phosphorous, and/or antimony, and the p-type dopants can comprise boron, gallium, and indium. The amorphous implants can comprise implanting silicon, germanium, antimony, indium, arsenic, neon, argon, krypton, xenon, or other suitable species. Following the implantation processes SPE and UHT annealing can be performed. In an embodiment of the instant invention the SPE anneal comprises annealing the amorphous implanted drain and source extension regions at temperatures from 550° C. to 950° C. for times from a few seconds to hundreds of seconds. In a further embodiment the SPE anneal is performed at temperatures around 900° C. for a few seconds to hundreds of seconds. In a further embodiment, the UHT anneal comprises annealing the implanted drain and source extension regions 230 at temperatures from 1050° C. to 1350° C. for 3 milliseconds to 0.5 milliseconds. The UHT anneals can comprise one such anneal or any number of annealing cycles. Following the formation of the drain and source extension regions 230, sidewall structures 240 are formed using standard semiconductor manufacturing methods. The MOS transistor drain and source regions 250 are formed by implanting n-type or p-type dopants into the semiconductor 200. An optional amorphizing implant can be performed prior to or following the dopant implantation process to form amorphous regions adjacent to the gate electrode 220 in the semiconductor 200. The n-type dopants and comprise arsenic, phosphorous, and/or antimony, and the p-type dopants can comprise boron, gallium, and indium. The amorphous implants can comprise implanting silicon, germanium, antimony, indium, arsenic, neon, argon, krypton, xenon, or other suitable species. Following the implantation processes SPE and UHT anneals can be performed. In an embodiment of the instant invention the SPE anneal comprises annealing the amorphous implanted drain and source regions 250 at temperatures from 550° C. to 950° C. for times from a few seconds to hundreds of seconds. In a further embodiment the UHT anneal comprises annealing the amorphous implanted drain and source regions 250 at temperatures from 1050° C. to 1350° C. for 3 milliseconds to 0.5 milliseconds. The UHT anneals can comprise one such anneal or any number of annealing cycles. In a further embodiment of the instant invention the UHT process following the implantation of the drain and source extension regions 230 can be omitted. In this embodiment the drain and source extension regions 230 and the drain and source regions 250 are annealed simultaneously using a common UHT process. In an embodiment of the instant invention the common UHT anneal comprises annealing the regions 230, 250 at temperatures from 1100° C. to 1350° C. for 3 milliseconds to 0.5 milliseconds. The UHT anneals can comprise one such anneal or any number of annealing cycles.

While this invention has been described with reference to illustrative embodiments, this description is not intended to be construed in a limiting sense. Various modifications and combinations of the illustrative embodiments, as well as other embodiments of the invention will be apparent to persons skilled in the art upon reference to the description. It is therefore intended that the appended claims encompass any such modifications or embodiments.

1. A method for forming ultra shallow junctions, comprising:
providing a semiconductor;
implanting a dopant species into said semiconductor; and
annealing said implanted semiconductor with a ultra high temperature anneal comprising annealing temperatures from 1050° C. to 1350° C.

2. The method of claim 1 further comprising an amorphizing implant.

3. The method of claim 2 wherein said amorphizing implant comprises implanting a species from the group consisting of silicon, germanium, antimony, indium, arsenic, neon, argon, krypton, and xenon.

4. The method of claim 1 wherein said ultra high temperature anneal comprises times from 0.5 milliseconds to 3 milliseconds.

5. A method for forming junction in integrated circuits, comprising:
providing a semiconductor;
forming a patterned photoresist layer on said semiconductor;
implanting dopant species into said semiconductor;
removing said patterned photoresist layer;
annealing said implanted semiconductor with a solid phase epitaxy anneal; and
annealing said implanted semiconductor with a ultra high temperature anneal comprising annealing temperatures from 1100° C. to 1350° C.

6. The method of claim 5 wherein said ultra high temperature anneal comprises times from 0.5 milliseconds to 3 milliseconds.

7. The method of claim 6 further comprising an amorphizing implant.

8. The method of claim 7 wherein said amorphizing implant comprises implanting a species from the group consisting of silicon, germanium, antimony, indium, arsenic, neon, argon, krypton, and xenon.

9. A method of forming a MOS transistor, comprising:
providing a semiconductor substrate;
forming a gate dielectric layer on said semiconductor;
forming a gate electrode on said gate dielectric layer;
implanting dopant species into said semiconductor adjacent to said gate electrode;
annealing said implanted semiconductor with a solid phase epitaxy anneal at a temperature between 550° C. and 950° C.; and annealing said implanted semiconductor with a ultra high temperature anneal comprising annealing temperatures from 1100° C. to 1350° C.

10. The method of claim 9 wherein said ultra high temperature anneal comprises times from 0.5 milliseconds to 3 milliseconds.

11. The method of claim 10 further comprising an amorphizing implant performed prior to said implanting of said dopant species.

12. The method of claim 11 wherein said amorphizing implant comprises implanting a species from the group consisting of silicon, germanium, antimony, indium, arsenic, neon, argon, krypton, and xenon.

13. A method of forming an integrated circuit MOS transistor, comprising:
providing a semiconductor substrate;
forming a gate dielectric layer on said semiconductor;
forming a gate electrode on said gate dielectric layer;
implanting first dopant species into said semiconductor adjacent to said gate electrode;
forming sidewall structures adjacent to said gate electrode;
implanting second dopant species into said semiconductor adjacent to said sidewall structures; and
annealing said implanted semiconductor with a ultra high temperature anneal comprising annealing temperatures from 1100° C. to 1350° C.

14. The method of claim 13 wherein said ultra high temperature anneal comprises times from 0.5 milliseconds to 3 milliseconds.

15. The method of claim 14 further comprising an amorphizing implant performed prior to said implanting of said first dopant species.

16. The method of claim 15 further comprising an amorphizing implant performed prior to said implanting of said second dopant species.

17. The method of claim 13 further comprising an amorphous implant performed prior to said implanting of said second dopant species.

18. The method of claim 16 wherein said amorphizing implants comprises implanting a species from the group consisting of silicon, germanium, antimony, indium, arsenic, neon, argon, krypton, and xenon.
